(19) United States
(12) Patent Application Publication
(10) Pub. No.: US 2025/0201637 A1
(43) Pub. Date: Jun. 19, 2025

(54) DEVICES AND METHODS FOR TESTING DIES WITH OFF-DIE CLOCKS

(71) Applicant: Advanced Micro Devices, Inc., Santa Clara, CA (US)

(72) Inventors: Russell Schreiber, Austin, TX (US); Shravan Lakshman, Austin, TX (US); John Wuu, Ft. Collins, CO (US)

(73) Assignee: Advanced Micro Devices, Inc., Santa Clara, CA (US)

(21) Appl. No.: 18/541,240

(22) Filed: Dec. 15, 2023

(51) Int. Cl. H01L 21/66; G01R 31/317; H01L 23/00; H03L 7/08

(52) U.S. Cl. CPC H01L 22/14; G01R 31/31727; H01L 24/80; H03L 7/08; H01L 2224/80895; H01L 2224/80896

(57) ABSTRACT

A device can include a clock synthesizer and a clock signal multiplexer that is configured to provide a signal from the clock synthesizer as output during a test mode and to provide a forwarded clock signal as output during an operational mode. Various other devices, systems, and methods are also disclosed.

### BACKGROUND

Stacked-die architectures involve vertically integrating multiple semiconductor dies within a single package. In some cases, individual dies can be tested before stacking.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a diagram of an example device for testing dies with off-die clocks.

FIG. 2 is a diagram of an example die with an integrated device for testing dies with off-die clocks.

FIG. 3 is a block diagram of an example test of a die using an integrated device for testing dies with off-die clocks.

FIG. 4 is a diagram of an example die stack including one die that forwards a clock signal to another die.

FIG. 5 is a diagram of an example die with an integrated device for testing dies with off-die clocks removed after testing.

FIG. 6 is a flow diagram of an example method of manufacture for die stacks.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to devices, systems, and methods of manufacture for testing dies with off-die clocks. Performing a wafer test of a die before it is stacked with another die can be important for manufacturing efficiency to ensure that only known-good dies are stacked with known-good dies. However, in some cases a stacked architecture can involve an off-die clock—where one die receives a clock signal from another die. Thus, to individually test the die that receives the forwarded signal, a wafer probe can provide a clock signal to the die. However, a wafer probe can have limitations. For example, a wafer probe can be limited in the frequency of signal which it can deliver. If the wafer probe cannot deliver a frequency to match the clock frequency that will be forwarded to the die in operation, then the test can be inadequate, potentially resulting in a bad die being stacked on a good die, wasting the good die.

Instead, a Phase-Locked Loop (PLL) or similar device can be multiplexed with the forwarded clock signal at the base of the clock distribution network. The PLL can be active only during testing, and can be inactive during (or removed before) the die is in an operational mode. This can allow for accurate die testing without wasting power or introducing other complexities.

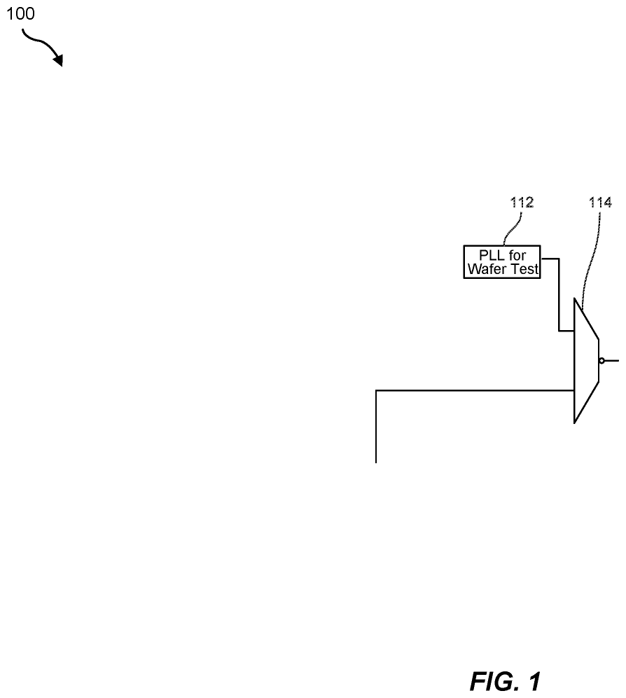

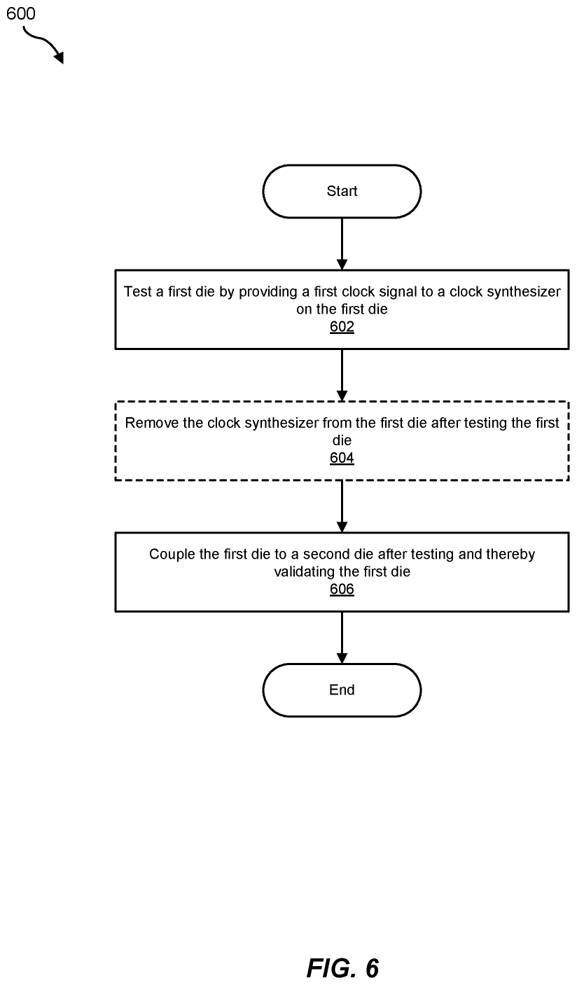

The following will provide, with reference to FIGS. 1-5, detailed descriptions of example devices and systems for testing dies with off-die clocks. Detailed descriptions of corresponding methods of manufacture will also be provided in connection with FIG. 6.

A device can include a clock synthesizer and a clock signal multiplexer. The clock signal multiplexer can be configured to supply a signal from the clock synthesizer as its output during a test mode and to give out a forwarded clock signal during an operational mode.

In some examples, the clock synthesizer includes a phase-locked loop.

In some examples, both the clock synthesizer and the clock signal multiplexer are components located within a single, first die.

In some examples, the forwarded clock signal is derived from a second die, which is arranged to be stacked on top of the first die.

In some examples, the output from the clock signal multiplexer serves as a clock signal for multiple devices present on the first die.

In some examples, the clock signal multiplexer's output is at the base of a clock distribution network on the first die.

In some examples, the device also includes a pad, which is configured to establish a connection with a probe. This pad is functionally connected to the clock synthesizer to supply input to it.

In some examples, the clock synthesizer is configured to accept an input of a clock signal at a predetermined frequency and subsequently produce an output of a clock signal at a different predetermined frequency.

In some examples, the device is further configured such that the clock synthesizer is disabled during the operational mode.

A system can include a first die, which includes a clock signal multiplexer. This multiplexer is configured to output a signal from a clock synthesizer when in test mode and to output a forwarded clock signal in an operational mode. The system also includes a second die that provides the forwarded clock signal to the first die, with the two dies being connected in a vertical stack.

In some examples, the first die also includes the clock synthesizer.

In some examples, the clock synthesizer is inactive during the operational mode.

In some examples, the first die is created from an original die. This process can involve the removal of a portion of the original die containing the clock synthesizer after the original die undergoes testing, with the clock synthesizer being employed during the test.

In some examples, the clock synthesizer includes a phase-locked loop.

In some examples, the first die is a memory die.

In some examples, the output from the clock signal multiplexer is provided as a clock signal for several devices located on the first die.

In some examples, the output of the clock signal multiplexer is at the base of the clock distribution network within the first die.

In some examples, the system can include a pad configured to interface with a probe, the pad being connected to the clock synthesizer, allowing the probe to provide input to the clock synthesizer.

A method of manufacture can include testing a first die. For example, the method can include providing a first clock signal to a clock synthesizer located on the first die. The die can include a clock signal multiplexer that is configured to distribute a signal from the clock synthesizer when in a test mode and to distribute a forwarded clock signal while in an operational mode. Following the testing, which confirms the first die's validity, the first die is coupled with a second die.

The method of manufacture can also include removing the clock synthesizer from the first die following the testing.

FIG. 1 is a diagram of an example device 100 for testing dies with off-die clocks. As shown in FIG. 1, device 100 can include a clock synthesizer 112 and a clock signal multiplexer 114. As used herein, the term “clock synthesizer” can refer to any device, circuitry, and/or module that produces a clock signal at a predetermined frequency. Thus, in some examples, a clock synthesizer can take another periodic signal (with, e.g., a clock signal with a frequency different from the target frequency of the clock synthesizer) as input and produce a clock signal with a target frequency as output. Examples of clock synthesizers include, without limitation, phase-locked loops, frequency synthesizers, and oscillator multipliers. In various examples, clock synthesizer can take a clock signal with a lower frequency as input and produce a clock signal with a higher frequency as output.

As shown in FIG. 1, clock signal multiplexer can have two inputs, one of which can be from clock synthesizer 112. As will be explained in greater detail below, while device 100 can be located on one die, in some examples the other input to clock signal multiplexer 114 can connect back to a different die (e.g., while one input to clock signal multiplexer 114 can be provided by clock synthesizer 112, the other input can be a clock signal originating from another die, when the two dies are coupled).

As used herein, the term “multiplexer” can refer to any circuitry, device, and/or module used to select between two or more signals to provide a single signal as output. In some examples, a control signal to a multiplexer can select which input signal to the multiplexer is used as an output signal to the multiplexer.

As will be explained in greater detail below, in some examples clock synthesizer 112 can receive input from a wafer probe during a die test to produce a test clock signal and clock signal multiplexer 114 can forward the test clock signal to a clock distribution network on a die. Later, when the tested and validated die is coupled to another die that provides an operational clock signal to clock signal multiplexer 114, clock signal multiplexer 114 can forward the operational clock signal to the clock distribution network.

As used herein, the term “clock distribution network” can refer to any circuitry that provides a clock signal to one or more elements on a die. In some examples, a clock distribution network can include a clock mesh and/or a clock tree.

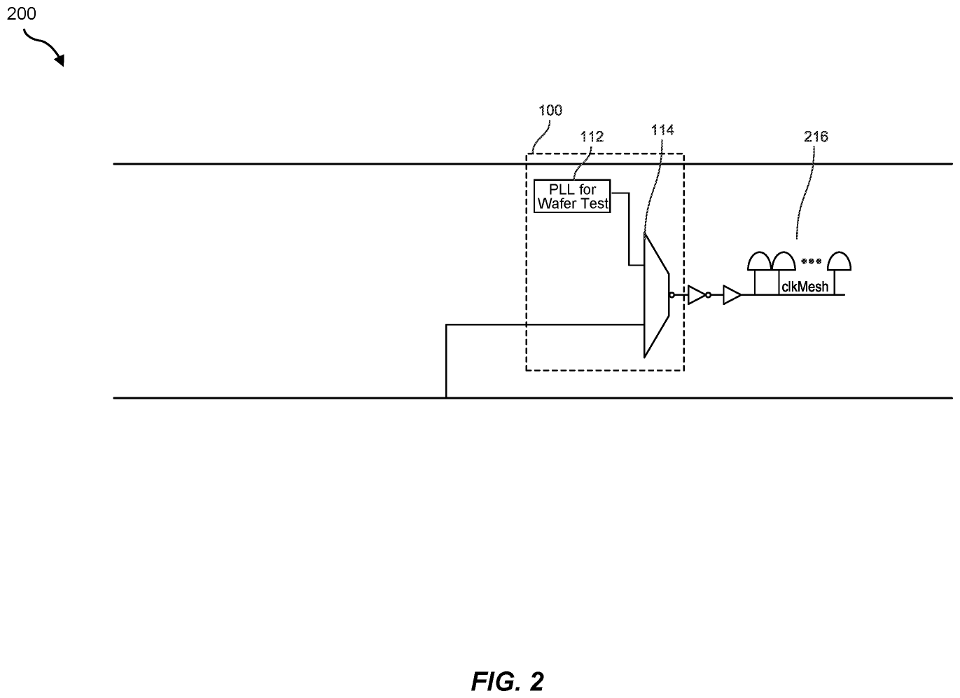

FIG. 2 is a diagram of an example die 200 with an integrated device for testing dies with off-die clocks. As shown in FIG. 2, die 200 can include device 100 from FIG. 1 (e.g., clock synthesizer 112 and clock signal multiplexer 114). In addition, die 200 can include a clock distribution network 216. As will be explained in greater detail below, in some examples die 200 does not have an on-die clock. Instead, die 200 can be forwarded a clock signal from another die when die 200 is stacked with the other die. However, die 200 can be tested individually (before stacking die 200 with the other die that forwards a clock signal) through the use of device 100.

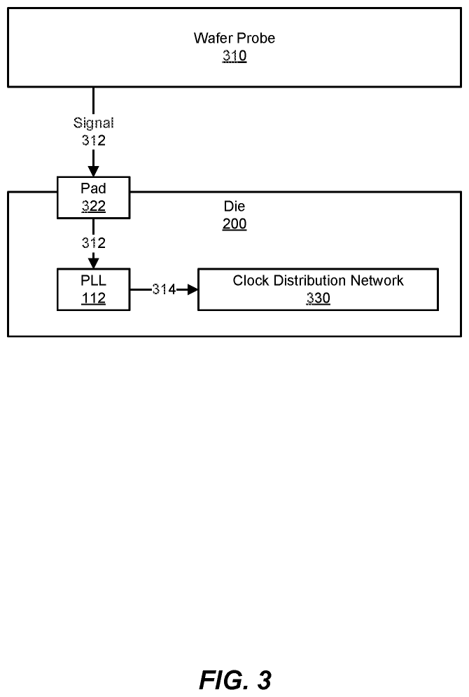

FIG. 3 is a block diagram of an example test of a die using an integrated device for testing dies with off-die clocks. As shown in FIG. 3, die 200 can be tested with the use of a wafer probe 310. In some examples, wafer probe 310 can interface with a pad 322 on die 200 to provide a signal 312 (e.g., a periodic signal). An interconnect from pad 322 can provide signal 312 as input to a clock synthesizer 112. In some examples, wafer probe 310 can only provide signals with a limited frequency range. However, die 200 can be configured to operate at a higher frequency than what wafer probe 310 can provide. Thus, clock synthesizer 112 can produce, as output a clock signal 314 at the frequency at which die 200 is configured to operate, thereby performing a more accurate test of die 200. Clock signal 314 may then propagate through a clock distribution network 330 on die 200.

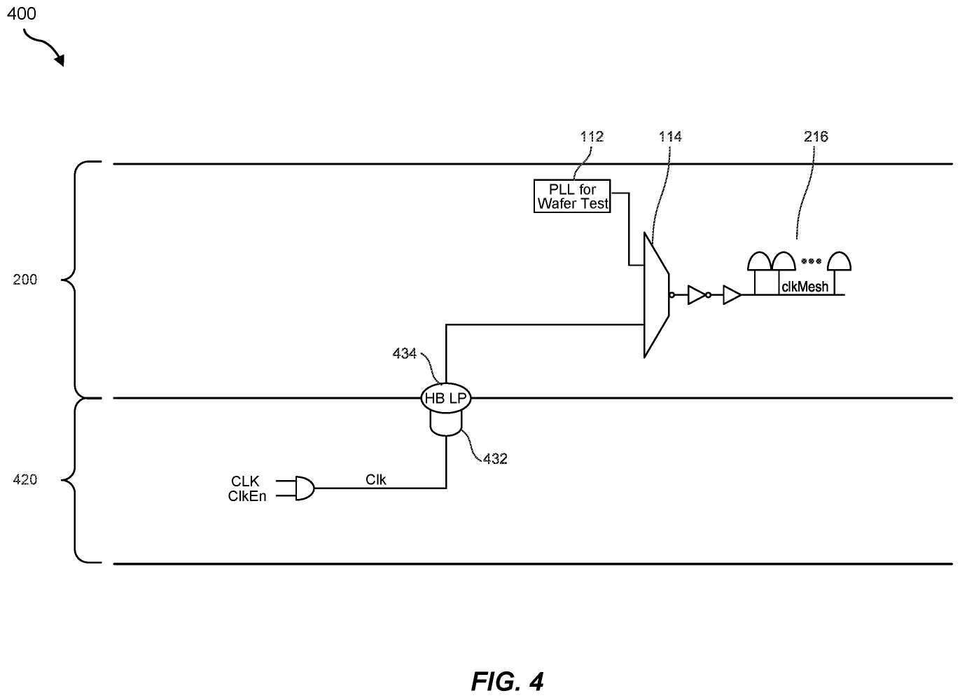

FIG. 4 is a diagram of an example die stack 400 including one die that forwards a clock signal to another die. As shown in FIG. 4, die stack 400 can include die 200 and a die 420. In some examples, die stack 400 can be formed on the basis of a successful test of die 200 (and, in some examples, of die 420). Because die 200 is a known-good die, it can be safely coupled to die 420 without risking that die 420 is wasted on a defective die. Thus, in one example, die 420 can transmit a clock signal to die 200 via a through-silicon via 432 and a hybrid bond landing pad 434.

Dies 200 and 420 can generally be any type of die. In some examples, die 200 can be a memory die and die 420 can be a processor die.

While clock synthesizer 112 can remain on die 200, in some examples clock synthesizer 112 can be disabled. Thus, for example, clock synthesizer 112 does not consume power as a part of die stack 400, nor does clock synthesizer 112 provide a signal to clock distribution network 216. Rather, clock signal multiplexer 114 outputs the clock signal forwarded from die 420.

While FIG. 4 shows two vertically stacked dies, the devices and systems described herein may generally apply to any two interconnected dies where one die forwards a clock signal to the other die. In another example, die 200 may be interconnected with die 420 by way of an interposer.

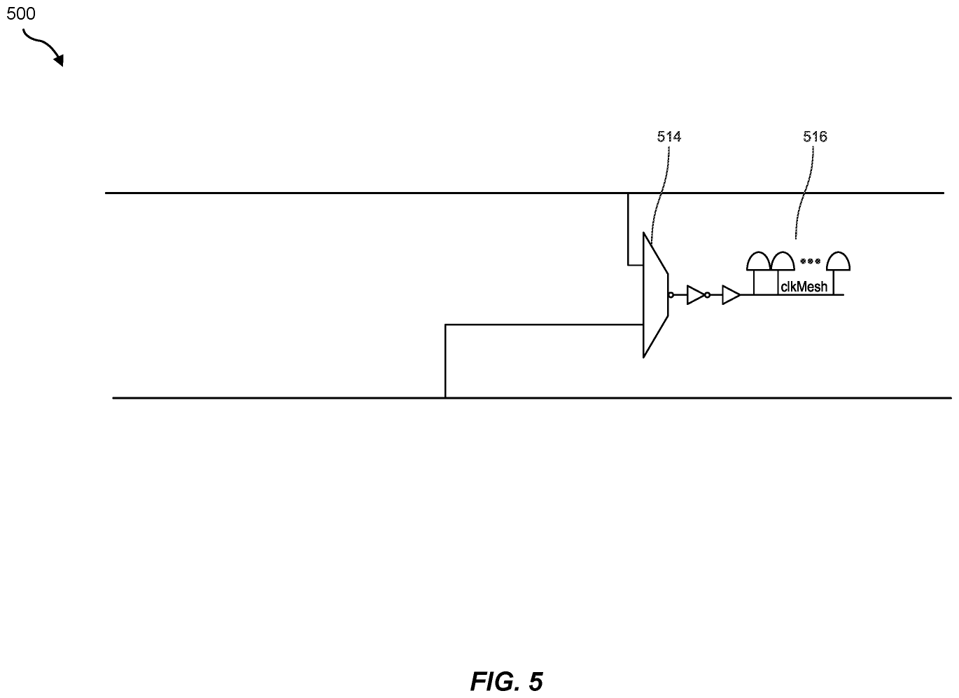

FIG. 5 is a diagram of an example die 500 with an integrated device for testing dies with off-die clocks removed after testing. In some examples, die 500 can be a modified version of die 200. For example, after die 200 is successfully tested, a portion of die 200 can be removed (decreasing the size of die 200), including the portion containing clock synthesizer 112. Die 500 can then be bonded to another die, such as die 420 of FIG. 4.

FIG. 6 is a flow diagram of an example method of manufacture 600 for die stacks. As shown in FIG. 6, at a step 602, method of manufacture 600 can include testing a first die by providing a first clock signal to a clock synthesizer on the first die. Thus, for example, the method can include interfacing a wafer probe with the first die (e.g., a pad on the first die connected to the clock synthesizer). The clock synthesizer can produce a modified clock signal with a frequency that matches the frequency at which the first die is configured to operate.

At an optional step 604, method of manufacture 600 can include removing the clock synthesizer from the first die after testing the first die. For example, method of manufacture 600 can include shaving the first die such that the clock synthesizer is removed from the first die. Because clock synthesizer is only needed for testing the first die, this optional step can reduce the space taken up by the first die.

At a step 606, method of manufacture 600 can include coupling the first die to a second die after testing and thereby validating the first die. For example, method of manufacture can include bonding the first die to a second die such that the second die forwards a clock signal to the first die. The first die can then operate at the frequency of the forwarded clock signal, which can be the same as the frequency of the clock signal produced by the clock synthesizer.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
a clock synthesizer; and
a clock signal multiplexer that is configured to provide a test signal from the clock synthesizer as output during a test mode and to provide a forwarded clock signal as output during an operational mode.

2. The device of claim 1, wherein the clock synthesizer comprises a phase-locked loop.

3. The device of claim 1, wherein the test signal and the forwarded clock signal have a same frequency.

4. The device of claim 1, wherein:
the clock synthesizer and the clock signal multiplexer are elements within a first die; and
the forwarded clock signal originates from a second die configured to be stacked with the first die.

5. The device of claim 4, wherein the output of the clock signal multiplexer provides a clock signal for a plurality of devices on the first die.

6. The device of claim 5, wherein the output of the clock signal multiplexer is at a base of a clock distribution network of the first die.

7. The device of claim 1, further comprising a pad configured to interface with a probe, wherein the pad is operatively connected to the clock synthesizer to provide input to the clock synthesizer.

8. The device of claim 1, wherein the clock synthesizer is configured to receive a clock signal at a first predetermined frequency as input and to produce a clock signal at a second predetermined frequency as output.

9. The device of claim 1, wherein the clock synthesizer is disabled during the operational mode.

10. A system comprising:
a first die comprising a clock signal multiplexer that is configured to provide a test signal from a clock synthesizer as output during a test mode and to provide a forwarded clock signal as output during an operational mode; and
a second die that provides the forwarded clock signal to the first die;
wherein the first die and the second die are interconnected.

11. The system of claim 10, wherein the first die further comprises the clock synthesizer.

12. The system of claim 11, wherein the clock synthesizer is disabled during the operational mode.

13. The system of claim 10, wherein the first die was derived from an original die by removing, after a test of the original die, a portion of the original die that included the clock synthesizer, the clock synthesizer being used for the test of the original die.

14. The system of claim 10, wherein the clock synthesizer comprises a phase-locked loop.

15. The system of claim 10, wherein the first die comprises a memory die.

16. The system of claim 10, wherein the output of the clock signal multiplexer provides a clock signal for a plurality of devices on the first die.

17. The system of claim 10, wherein the output of the clock signal multiplexer is at a base of a clock distribution network of the first die.

18. The system of claim 10, further comprising a pad configured to interface with a probe, wherein the pad is operatively connected to the clock synthesizer to provide input to the clock synthesizer.

19. A method of manufacture comprising:
testing a first die by providing a first clock signal to a clock synthesizer on the first die, wherein a clock signal multiplexer on the first die is configured to provide a test signal from the clock synthesizer as output during a test mode and to provide a forwarded clock signal as output during an operational mode; and
coupling the first die to a second die after testing and thereby validating the first die.

20. The method of manufacture of claim 19, further comprising removing the clock synthesizer from the first die after testing the first die.
